(19) United States
(12) Patent Application Publication
(10) Pub. No.: US 2023/0039359 A1
(43) Pub. Date: Feb. 9, 2023

(54) SEMICONDUCTOR DEVICE AND METHOD OF MANUFACTURING THE SAME

(71) Applicant: RENESAS ELECTRONICS CORPORATION, Tokyo (JP)

(72) Inventors: Yasutaka NAKASHIBA, Tokyo (JP); Masami SAWADA, Tokyo (JP)

(21) Appl. No.: 17/838,707

(22) Filed: Jun. 13, 2022

(30) Foreign Application Priority Data
Aug. 5, 2021 (JP) 2021-128889

(51) Int. Cl. H01L 29/06; H01L 29/10; H01L 29/78; H01L 21/265; H01L 21/266; H01L 21/306; H01L 29/66

(52) U.S. Cl. CPC H01L 29/0634; H01L 29/1095; H01L 29/7813; H01L 21/26513; H01L 21/26586; H01L 21/266; H01L 21/30604; H01L 29/66734

(57) ABSTRACT

Variations of characteristics of a semiconductor device provided with a power MOSFET having a super junction structure are suppressed, and reliability of the semiconductor device is improved. A trench embedding an insulating film, which constitutes an insulator column therein, is formed in a first main surface of a semiconductor substrate whose crystal plane is a (110) plane. A crystal plane of a side surface of the trench in a short-side direction is a (111) plane, and a p-type diffusion layer constituting a p-column is formed in the above-mentioned side surface.

### CROSS-REFERENCE TO RELATED APPLICATIONS

The present application claims priority from Japanese Patent Application No. 2021-128889 filed on Aug. 5, 2021, the content of which is hereby incorporated by reference to this application.

### BACKGROUND

The present invention relates to a semiconductor device and a method of manufacturing the same, for example, a technique effectively applicable to a semiconductor device and a method of manufacturing the same, the semiconductor device being provided with a vertical field effect transistor having a trench that is formed on an upper surface of a semiconductor substrate.

A super junction structure is known as a structure of a power MOSFET (Metal Oxide Semiconductor Field Effect Transistor). The super junction structure is a structure including: a gate electrode in a trench formed in the upper surface of the semiconductor substrate; an n-type layer in the semiconductor substrate under the trench; and a p-type layer interposing the n-type layer. Known as a method of forming the p-type layer is a method in which a trench is formed in the upper surface of the semiconductor substrate and then a p-type impurity is introduced into a side surface of the trench by an oblique ion implantation method.

Patent Document 1 (Japanese Patent Application Laid-open No. 2017-143188) discloses a semiconductor device which includes an insulated gate type field effect transistor section having a super junction structure and a snubber section.

### SUMMARY

Generally, the trench formed in the upper surface of the semiconductor substrate is formed by using dry etching. Consequently, it is difficult to stably form the trench and its side surface with respect to the upper surface. Further, the trench has an angle (trench angle) with respect to the upper surface, and a width of an upper end of the trench is generally wider than that of a lower end of the trench. When the trench angle varies due to manufacturing variations and if a plurality of p-type layers described above are formed by the oblique ion implantation method as described above, an amount of impurities injected into the p-type layer varies due to the variations in the trench angle. Thus, a problem arises in that it is difficult to stabilize the variations in characteristics (withstand voltage) of the power MOSFET.

Other problems and novel features will become apparent from the description herein and the accompanying drawings.

The following is a brief description of an outline of the typical invention disclosed in the present application.

A semiconductor device according to one embodiment includes a trench embedding an insulating film that constitutes an insulator column therein, the trench being formed in a first main surface of a semiconductor substrate whose crystal plane is a (110) plane. A crystal plane of a side surface of the trench in a short-side direction is a (111) plane, and a diffusion layer constituting a column of a predetermined conductive type is formed in the above-mentioned side surface.

According to an embodiment, reliability of the semiconductor device can be improved.

### BRIEF DESCRIPTION OF THE DRAWINGS

FIG. 1 is a planar layout showing a semiconductor device which is an embodiment.

FIG. 2 is a sectional view taken along line A-A of FIG. 1.

FIG. 3 is sectional view showing a method of manufacturing a semiconductor device according to an embodiment.

FIG. 4 is a sectional view showing the method of manufacturing the semiconductor device following FIG. 3.

FIG. 5 is a sectional view showing the method of manufacturing the semiconductor device following FIG. 4.

FIG. 6 is a sectional view showing the method of manufacturing the semiconductor device following FIG. 5.

FIG. 7 is a sectional view showing the method of manufacturing the semiconductor device following FIG. 6.

FIG. 8 is a sectional view showing the method of manufacturing the semiconductor device following FIG. 7.

FIG. 9 is a sectional view showing the method of manufacturing the semiconductor device following FIG. 8.

FIG. 10 is a sectional view showing the method of manufacturing the semiconductor device following FIG. 9.

FIG. 11 is a sectional view showing the method of manufacturing the semiconductor device following FIG. 10.

FIG. 12 is a sectional view showing the method of manufacturing the semiconductor device following FIG. 11.

FIG. 13 is a planar layout showing a semiconductor device which is a modification example of the embodiment.

### DETAILED DESCRIPTION

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle, and the number larger or smaller than the specified number is also applicable.

Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Hereinafter, embodiments of the present invention will be described in detail with reference to the accompanying drawings. Note that components having the same function are denoted by the same reference characters throughout the drawings for describing the embodiments, and a repetitive description thereof will be omitted. In addition, the description of the same or similar portions is not repeated in principle unless particularly required in the following embodiments.

Further, the symbols “−” and “+” are codes indicating that a conductive type has a relative n-type or p-type impurity concentration and, for example, the n-type impurity concentration becomes high in the order of “n⁻⁻”, “n⁻”, “n”, “n⁺”, and “n⁺⁺”.

<Structure of Semiconductor Device>

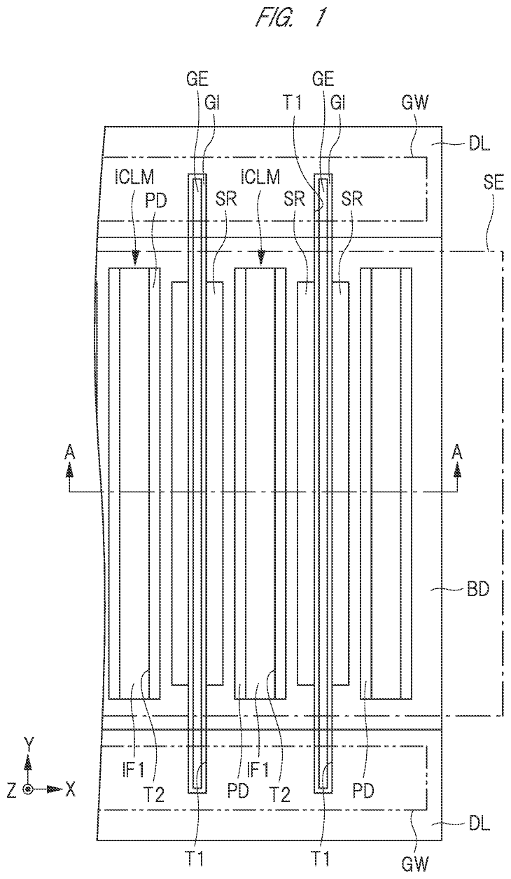

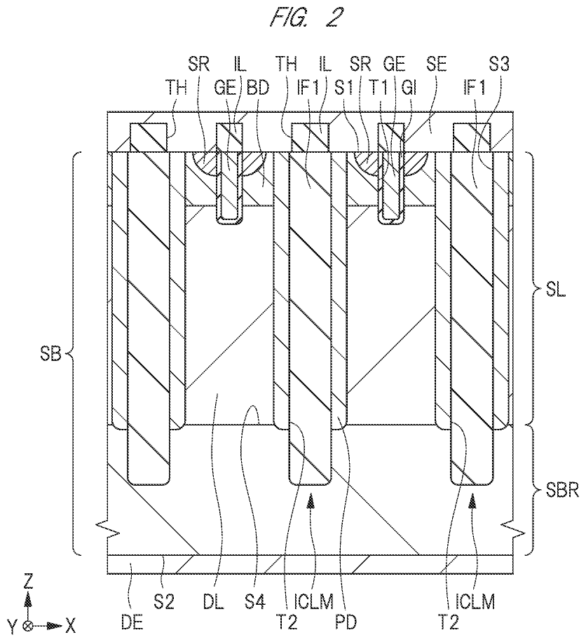

Hereinafter, a structure of a semiconductor device of the present embodiment will be described with reference to FIGS. 1 and 2. A semiconductor device of this embodiment has a vertical power MOSFET (MOS type field effect transistor) having a super junction structure. A semiconductor substrate referred to in the present application may constitute an individualized semiconductor chip or may constitute a semiconductor wafer before individualization.

FIG. 1 shows a first main surface (upper surface) of the semiconductor substrate. In FIG. 1, illustration of an interlayer insulating film on the semiconductor substrate is omitted. Further, in FIG. 1, an outline of a source electrode SE is shown by a dash-single-dot line, and an outline of a gate wiring GW is shown by a dash-double-dot line. The first main surface of the semiconductor substrate is a surface along X and Y directions orthogonal to each other in a plan view. A normal direction of the first main surface of the semiconductor substrate is a Z direction orthogonal to each of the X direction and the Y direction. The plan view as used in the present application means a case where the first main surface of the semiconductor substrate is looked down in a −Z direction.

As shown in FIG. 1, a plurality of trenches T1 each having a predetermined depth extending in the Y direction are formed alongside in the X direction in the first main surface of the semiconductor substrate. A gate electrode GE is embedded in the trench T1 via a gate insulating film GI. Further, a plurality of trenches T2 each having a predetermined depth extending in the Y direction are formed alongside in the X direction in the first main surface of the semiconductor substrate. The depth of the trench T2 is deeper than that of the trench T1. The trench T1 and the trench T2 are alternately arranged in the X direction. An insulating film IF1 is embedded in the trench T2. The insulating film IF1 constitutes an insulator column ICLM. Each of the trenches T1 and T2 has two side surfaces facing each other in the X direction.

Here, main features of the present embodiment are, for example, that a crystal plane of the first main surface of the semiconductor substrate is a (110) plane and a crystal plane on a side surface of the trench T2 in the X direction (in a short-side direction of the trench T2) is a (111) plane.

A body region BD is formed in the semiconductor substrate between the trenches T1 and T2 adjacent to each other in the X direction. Further, an n-type source region SR is formed on an upper surface of the body region BD adjacent to the trench T1 in the X direction. Furthermore, a p-type diffusion layer PD is formed in the semiconductor substrate adjacent to the trench T2 in the X direction. The source region SR is separated from the trench T2, and the diffusion layer PD is separated from the trench T1. The diffusion layer PD constitutes a p-column.

In the Y direction, the trench T1 extends longer than the trench T2. The gate electrode GE in the trench T1 is electrically connected to a gate wiring GW on the semiconductor substrate. Further, the source region SR, the body region BD, and the diffusion layer PD are electrically connected to a source electrode SE on the semiconductor substrate.

As shown in FIG. 2, the semiconductor device of the present embodiment has a semiconductor substrate SB. The semiconductor substrate SB has a first main surface (upper surface) S1 and a second main surface (lower surface) S2 parallel to each other. The first main surface S1 and the second main surface S2 of the semiconductor substrate SB extend along the X and Y directions orthogonal to each other. The semiconductor substrate SB includes a substrate region SBR and a semiconductor layer SL on the substrate region SBR. In this case, an upper surface of the semiconductor layer SL constitutes the first main surface S1 of the semiconductor substrate SB, and a lower surface of the substrate region SBR constitutes the second main surface S2 of the semiconductor substrate SB. Here, a crystal plane of the first main surface of the upper surface (first main surface S1) of the semiconductor layer SL is the (110) plane.

The substrate region SBR is composed of an n-type semiconductor. The substrate region SBR has, for example, an electrical resistivity of 5 mΩ·cm or less. The substrate region SBR is composed of, for example, n⁺ type single crystal silicon. The semiconductor layer SL has a drift layer DL, which is mainly an n-type semiconductor region, and contains n-type impurities. A thickness of the semiconductor layer SL is determined according to a withstand voltage of the power MOSFET. The substrate region SBR has a relatively lower electrical resistivity than that of the semiconductor layer SL. A concentration of n-type impurities in the substrate region SBR is relatively higher than a concentration of n-type impurities in the semiconductor layer SL.

The power MOSFET of the present embodiment includes an n-type drift layer DL, a p-type body region BD, an n-type source region SR, a gate insulating film GI, a gate electrode GE, and a source electrode SE. That is, the power MOSFET is an n-type field effect transistor. Further, the substrate region SBR constitutes a drain region of the power MOSFET. The power MOSFET further includes a drain electrode DE, a diffusion layer PD which is a p-column, and an interlayer insulating film IL. The gate electrode GE is formed in the trench T1, which is formed in the first main surface S1 of the semiconductor substrate SB, via the gate insulating film GI. The insulator column ICLM includes an insulating film in the trench T2 formed in the first main surface S1 of the semiconductor substrate SB.

The n-type drift layer DL is arranged in the semiconductor substrate SB. The drift layer DL is arranged on the substrate region SBR. The drift layer DL has an n-type impurity concentration lower than that of the substrate region SBR. The drift layer DL has a higher electrical resistivity than that of the substrate region SBR. The drift layer DL is, for example, an n⁻ type silicon layer.

The body region BD, which is a p-type semiconductor region, is arranged on the drift layer DL in the semiconductor substrate SB. The body region BD is, for example, a p-type silicon layer.

The source region SR, which is an n-type semiconductor region, is arranged on the body region BD in the semiconductor substrate SB. Specifically, the source region SR contacts with the trench and is formed from the upper surface of the semiconductor layer SL to a middle depth of the semiconductor layer SL. The n-type source region SR has a higher concentration of n-type impurities than that of the drift layer DL. The source region SR has a lower electrical resistivity than that of the drift layer DL. The source region SR is discretely arranged along the X direction in the first main surface S1 of the semiconductor substrate SB. The source region SR extends along the Y direction. The source region SR is, for example, an n⁺ type silicon region.

A trench T1 is a relatively shallow groove formed in the upper surface of the semiconductor layer SL. The trench T1 is formed at a position sandwiched between the source regions SR arranged in the X direction and contacts with the source regions SR. In contrast, a trench T2 is a relatively deep groove formed in the upper surface of the semiconductor layer SL. The trench T2 and each of the two source regions SR adjacent to the trench T1 are separated from each other via the body region BD. Each of the adjacent trenches T1 and T2 in the X direction contacts with one body region BD formed between them. A bottom of the trench T1 is terminated at the middle depth of the drift layer DL below the body region BD, and does not reach the substrate region SBR. In contrast, a bottom of the trench T2 reaches the middle depth of the substrate region SBR. However, the bottom of the trench T2 may be terminated in the drift layer DL and may not reach the substrate region SBR. Even in that case, the trench T2 is deeper than the trench T1.

The gate insulating film GI continuously covers a side surface and a bottom surface of the trench T1. A portion of the body region BD, which is sandwiched between the drift layer DL and the source region SR and is adjacent to the trench T1, is a portion at which a channel is formed in an ON state of the power MOSFET. The gate insulating film GI is arranged on a portion of the body region BD sandwiched between the drift layer DL and the source region SR. The trench T1 is arranged over the body region BD and the n-type drift layer DL. The gate insulating film GI contacts with the p-type body region BD and the n-type drift layer DL. The gate insulating film GI is, for example, a silicon oxide film.

The gate electrode GE interposes the gate insulating film GI, and is arranged so as to face a portion of the body region BD sandwiched between the drift layer DL and the source region SR. That is, the gate electrode GE is formed in the trench T1 via the gate insulating film GI. The gate electrode GE is a trench gate type gate electrode. Incidentally, the gate electrode GE may be a planar type gate electrode GE formed on the semiconductor layer SL instead of the trench gate type. The gate electrodes GE are arranged discretely along the X direction. The gate electrode GE extends along the Y direction. A height (depth) of the gate electrode GE in the Z direction is larger than the depth of the body region BD in the Z direction. The gate electrode GE is, for example, a polycrystalline silicon film. The gate electrode GE is electrically connected to the gate wiring GW (see FIG. 1) via a contact hole (not shown).

The insulator column ICLM is arranged in the trench T2. The insulator column ICLM is arranged throughout in the drift layer DL, the body region BD, and the substrate region SBR. That is, the insulator column ICLM is arranged in the trench T2 that is formed over in the drift layer DL, the body region BD, and the substrate region SBR. The insulator column ICLM is arranged on the first main surface S1 side of the semiconductor substrate SB. The insulating film IF1 is embedded in the trench T2.

The insulator column ICLM is arranged between the adjacent gate electrodes GE in a plan view from the Z direction. A plurality of insulators column ICLM are formed. The insulator columns ICLM adjacent to each other in the X direction are arranged so as to interpose the gate electrode GE in a plan view from the Z direction. The plurality of insulator columns ICLM are arranged discretely in the X direction. Each of the plurality of insulator columns ICLM extends along the Y direction.

The interlayer insulating film IL is arranged on the first main surface S1 of the semiconductor substrate SB. The interlayer insulating film IL has a through hole TH. The interlayer insulating film IL is, for example, a silicon oxide film. The source electrode SE is arranged on the first main surface S1 of the semiconductor substrate SB. The source electrode SE is formed in the through hole TH and on the interlayer insulating film IL. Through a contact hole arranged in the through hole TH, the source electrode SE is electrically connected to the source region SR and the p-type body region BD. The source electrode SE is, for example, an Al (aluminum) film.

The drain electrode DE is arranged on a second main surface S2 of the semiconductor substrate SB (substrate region SBR). The drain electrode DE is electrically connected to the drift layer DL via the substrate region SBR. The power MOSFET is a MOSFET having a vertical structure. The drain electrode DE is, for example, an aluminum (Al) film.

The power MOSFET of the present embodiment has a super junction structure in which a p-column provided with a p-type diffusion layer PD and an n-type drift layer DL (n-column) are alternately arranged in the X direction. Incidentally, the two diffusion layers PD sandwiching the insulator column ICLM are considered as one p-column.

<Operation of Semiconductor Device>

In the power MOSFET of the present embodiment which has the super junction structure, an n-type drift layer DL (n-column) and a p-column provided with a p-type diffusion layer PD are alternately arranged in the drift layer DL. When a voltage is applied between the source and the drain with the power MOSFET turned off, a depletion layer spreads in the drift layer DL in the X direction from each of the diffusion layers PD interposing the drift layer DL. By integrating these depletion layers with each other, the depletion layer corresponding to a depth of the groove is formed. Therefore, even if the impurity concentration of the drift layer DL is set relatively high, the withstand voltage can be ensured, so that on-resistance can be reduced.

<Method of Manufacturing Semiconductor Device>

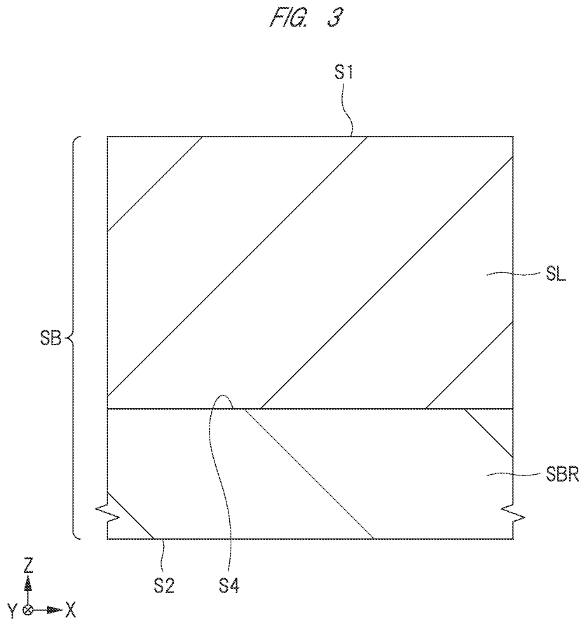

Hereinafter, an example of a method of manufacturing a semiconductor device according to the present embodiment will be described with reference to FIGS. 3 to 12.

A method of manufacturing a semiconductor device according to the present embodiment includes, as shown in FIG. 3, a step of preparing a semiconductor substrate SB having a first main surface S1 and a second main surface S2 parallel to each other. In the step of preparing the semiconductor substrate SB, after preparing an n-type substrate region SBR, a semiconductor layer SL is formed on the substrate region SBR. The semiconductor layer SL is included in the semiconductor substrate SB. An upper surface of the semiconductor layer SL constitutes a first main surface S1. A lower surface of the substrate region SBR constitutes a second main surface S2. The semiconductor layer SL contains a p-type impurity and has a p-type. Specifically, the step of preparing the semiconductor substrate SB includes epitaxially growing a p-type semiconductor layer SL on the n⁺ type substrate region SBR.

A crystal plane of the first main surface of the semiconductor substrate is a (110) plane. Further, inside the semiconductor layer SL, a crystal plane that is a plane perpendicular to the X direction is a (111) plane.

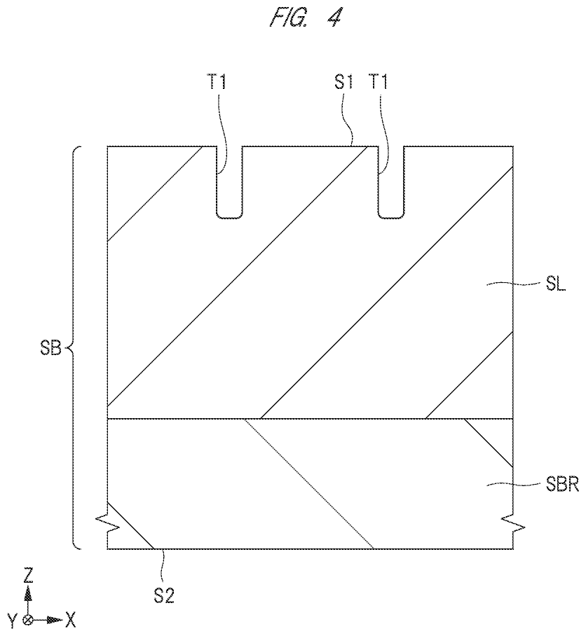

Next, as shown in FIG. 4, a plurality of trenches T1 are formed in the first main surface S1 of the semiconductor substrate SB (semiconductor layer SL). By anisotropically etching the first main surface S1 of the semiconductor substrate SB (semiconductor layer SL), the trenches T1 are formed in the first main surface S1 of the semiconductor substrate SB (semiconductor layer SL). The trench T1 can be formed by, for example, dry etching, but here, it is formed by wet etching using TMAH (tetramethylammonium hydroxide). The crystal plane of a side surface of the trench T1 in the X direction (a short-side direction of the trench T1) is the (111) plane.

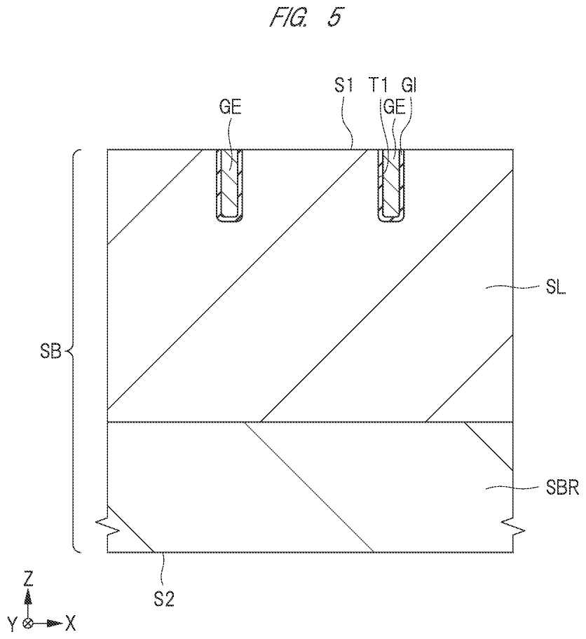

Next, as shown in FIG. 5, a gate electrode GE is formed in the trench T1 via a gate insulating film GI.

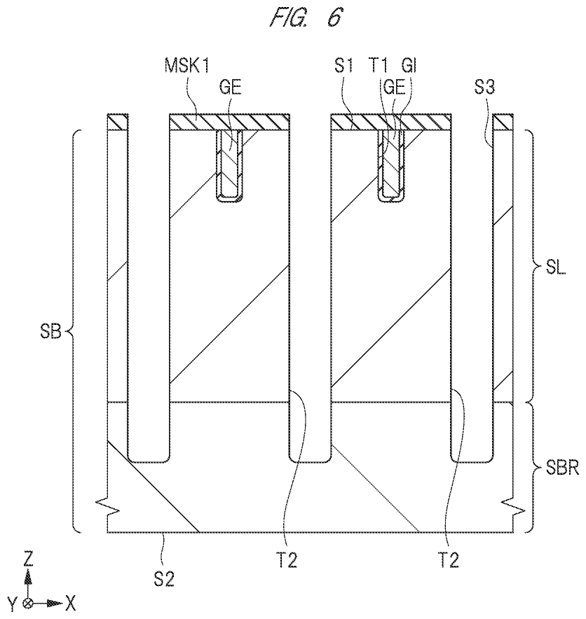

Next, as shown in FIG. 6, a plurality of trenches (column grooves) T2 are formed in the first main surface S1 of the semiconductor substrate SB (semiconductor layer SL). Specifically, a first mask MSK1 having an opening is formed on the first main surface S1 of the semiconductor substrate SB (semiconductor layer SL). The first mask MSK1 is made of, for example, silicon dioxide or a photoresist. The semiconductor substrate SB (semiconductor layer SL) is anisotropically etched by using the first mask MSK1. A crystal plane of a side surface S3 of the trench T2 thus formed in the X direction (a short-side direction of the trench T2) is the (111) plane.

In this etching step, the semiconductor substrate SB is etched by a wet etching method using TMAH as an etching solution. TMAH is used as a positive resist developer for lithography in a manufacturing process of a semiconductor device, and has an advantage of having a high affinity for semiconductors and its manufacturing process. The etching using TMAH has a characteristic of an etching rate of the (111) plane of the semiconductor layer being much slower than an etching rate of the (110) plane. For this reason, when wet etching using TMAH is performed onto the first main surface S1 having the crystal plane of the (110) plane, the (111) plane which is a side surface S3 of the trench T2 is hardly removed. As a result, the trench T2 having the side surface S3 substantially perpendicular to the first main surface S1 can be formed. That is, it is possible to reduce variations in angles (trench angles) of the respective side surfaces S3 of the plurality of trenches T2 formed in the first main surface S1 of the semiconductor substrate SB (semiconductor layer SL).

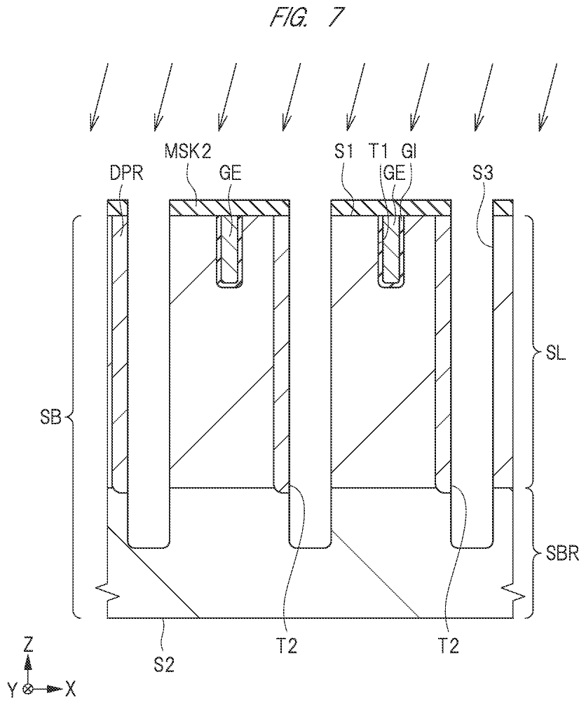

Next, as shown in FIG. 7, after removing the first mask MSK1, an n-type impurity-containing region DPR is formed on the side surface S3 of the trench T2. A step of forming the n-type impurity-containing region DPR includes doping the side surface S3 of the trench T2 with the n-type impurity from a direction inclined with respect to a normal direction (Z direction) of the first main surface S1. The n-type impurity is, for example, phosphorus (P).

Specifically, as shown in FIG. 7, a second mask MSK2 having an opening is formed on the first main surface S1 of the semiconductor substrate SB. The second mask MSK2 is made of, for example, silicon dioxide or a photoresist. Alternatively, the first mask MSK1 may be used, as it is, as the mask MSK2 without being removed. An n-type impurity is ion-implanted into the side surface S3 on the −X direction side of the trench T2 from a direction inclined in the +X direction with respect to the normal direction (Z direction) of the first main surface S1. Consequently, an n-type impurity-containing region DPR is formed on one side surface S3 of the trench T2.

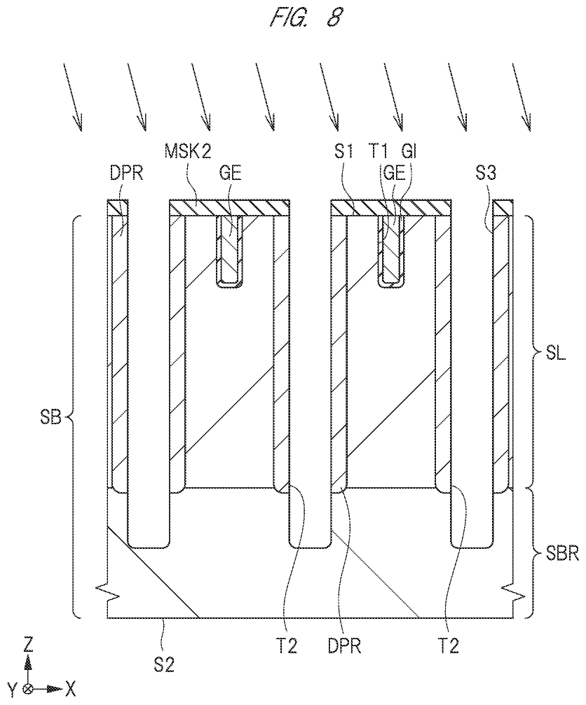

Next, as shown in FIG. 8, an n-type impurity is ion-implanted into the side surface S3 on the +X direction side of the trench T2 from a direction inclined in the −X direction with respect to the normal direction (Z direction) of the first main surface S1. Consequently, an n-type impurity-containing region DPR is formed on the other side surface S3 of the trench T2.

Next, although not shown, an n-type drift layer DL is formed in the semiconductor substrate SB. Specifically, the drift layer DL is formed by diffusing the n-type impurities, which are doped in the side surface S3 of the trench T2, into the semiconductor layer SL by a method such as a thermal diffusion method. For example, by performing a heat treatment at a temperature of 1000° C. or higher and 1200° C. or lower, the n-type impurities doped in the side surfaces S3 of the plurality of trenches T2 are activated and diffused in the drift layer. In this way, the n-type drift layer DL is formed around the trench T2. In other words, the trench T2 is formed in the drift layer DL.

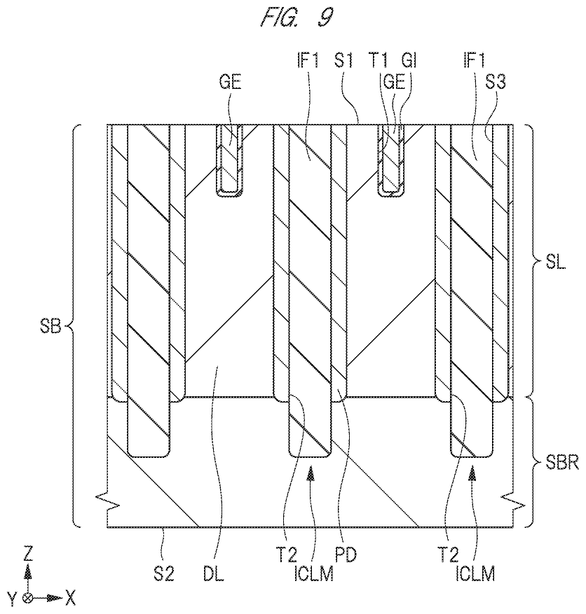

Next, as shown in FIG. 9, after removing the second mask MSK2, a plurality of p⁺ type diffusion layers PD (p-columns, semiconductor columns) are formed in the drift layer DL. Specifically, at least one diffusion layer PD is formed along the side surface S3 of the trench T2 in the drift layer DL. The plurality of diffusion layers PD are formed along both the X-directional side surfaces S3 of each of the plurality of trenches T2 in the drift layer DL.

Specifically, a third mask MSK (not shown) having an opening is formed on the first main surface S1 of the semiconductor substrate SB. The third mask MSK is made of, for example, silicon dioxide or a photoresist. Alternatively, a mask MASK3 may be used, as it is, without removing the first or second mask. By the same process as the process shown in FIGS. 7 and 8, the side surface S3 of the trench T2 is doped with p-type impurities from a direction inclined with respect to the normal direction of the first main surface S1. The p-type impurity is, for example, boron (B). Then, for example, by performing a heat treatment at a temperature of 800° C. or higher and 900° C. or lower, the p-type impurities doped in the side surface S3 of the trench T2 are activated. In this way, the p-type diffusion layer PD is formed. Consequently, formed is a super junction structure in which the p-type diffusion layer PD and the n-type drift layer DL are alternately arranged in the X direction.

Subsequently, an insulator column ICLM is formed in the trench T2. The insulator column ICLM is formed by leaving an insulating film (for example, a silicon oxide film), which is formed on the semiconductor substrate SB by a deposition method such as a CVD (Chemical Vapor Deposition) method, only in the trench T2. That is, the insulating film on the first main surface S1 among the insulating films formed on the semiconductor substrate SB including an inside of the trench T2 is removed by a CMP (Chemical Mechanical Polishing) method or the like. This makes it possible to form the insulator column ICLM made of an insulating film filled in the trench T2.

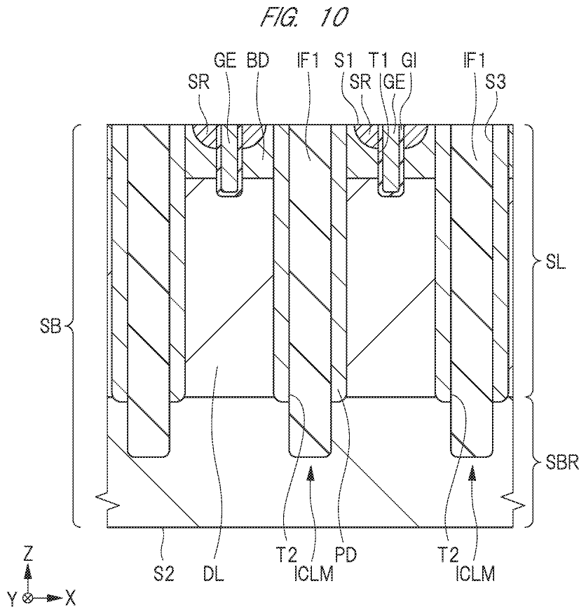

Next, as shown in FIG. 10, a body region BD and an n-type source region SR are formed. The body region BD is formed on the first main surface S1 side of the drift layer DL in the semiconductor substrate SB. The body region BD has a p-type. The body region BD interposes the gate insulating film GI and is formed at a position facing the gate electrode GE. The body region BD is formed by doping the first main surface S1 of the drift layer DL with a p-type impurity. The source region SR is formed on the first main surface S1 side of the body region BD in the semiconductor substrate SB. The source region SR is formed by doping the first main surface S1 of the body region BD with an n-type impurity. The source region SR is formed on the first main surface S1 adjacent to the gate electrode GE in a plan view. The source region SR is, for example, an n⁻ type region. The gate electrode GE interposes the gate insulating film GI and is formed so as to face a portion of the body region BD.

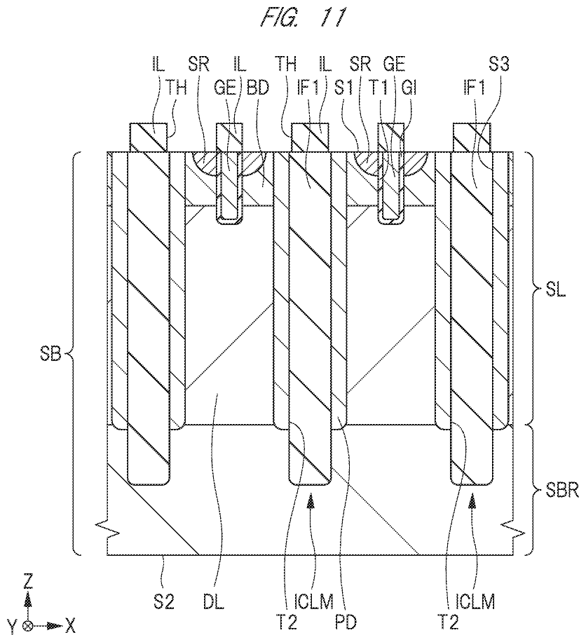

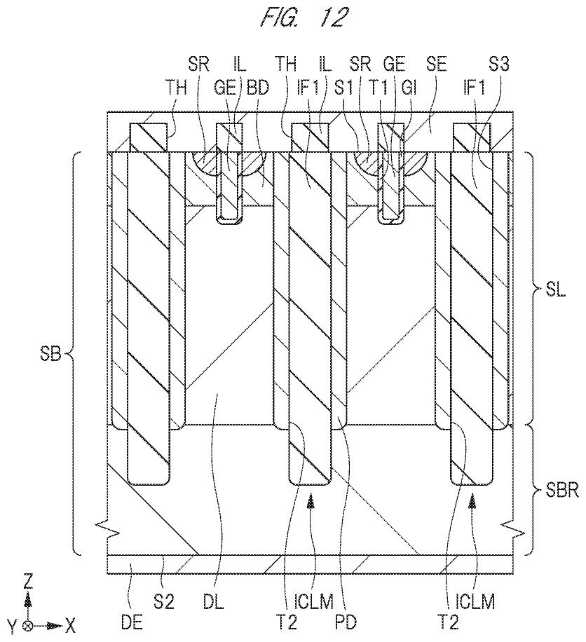

Next, as shown in FIG. 11, an interlayer insulating film IL having a through hole TH is formed on the first main surface S1 of the semiconductor substrate SB. Subsequently, as shown in FIG. 12, a source electrode SE is formed on the first main surface S1 of the semiconductor substrate SB. Thereafter, a drain electrode DE is formed on the second main surface S2 of the semiconductor substrate SB. The source electrode SE is electrically connected to the source region SR via a contact hole which is the through hole TH of the interlayer insulating film IL. The p-type body region BD and the diffusion layer PD are electrically connected to the source electrode SE. The substrate region SBR including the drain region is electrically connected to the drain electrode DE. By the above-mentioned steps, the semiconductor device of the present embodiment is manufactured.

### Effect of Present Embodiment

In the power MOSFET having the super junction structure, it is conceivable to form the trench in the upper surface of the semiconductor substrate and introduce the impurities into the side surface of the trench to form the n-column or the p-column. In this case, for example, the crystal plane of the upper surface (first main surface) of the semiconductor substrate is the (100) plane. Here, when the trench is formed by dry etching, the side surface of the trench is formed obliquely with respect to the thickness direction (Z direction) of the semiconductor substrate, so that the trench has a trench angle. For example, in forming a p-type diffusion layer on the side surface of the trench, p-type ions are implanted into a surface of the semiconductor substrate with a tilt angle of, for example, 1 degree to 10 degrees in the Z direction by an oblique ion implantation method. Consequently, a p⁺ type diffusion layer is formed in the semiconductor substrate that contacts with the side surface of the trench.

Here, it is conceivable that the trench angle on each side surface of the plurality of trenches may cause variations for each trench, chip, and/or wafer. In that case, a problem arises in that an amount of impurities injected into the diffusion layer varies due to production variations of trenches. If the amount of impurities injected into the diffusion layer varies, the characteristics (withstand voltage) of the power MOSFET will vary, so that reliability of the semiconductor device will deteriorate.

In contrast, in the present embodiment, the plurality of trenches T2, in which the crystal plane of the first main surface (upper surface) S3 is the (111) plane, are formed in the semiconductor substrate SB in which the crystal plane of the first main surface (upper surface) S1 is the (110) plane. Since the etching for forming the trench T2 is performed by wet etching using TMAH, an etching rate of the side surface S3 of the trench T2 can be made extremely small. Therefore, the plurality of trenches T2 each having a trench angle close to vertical can be stably formed.

Consequently, the n-column formed by performing the oblique ion implantation into the side surface S3 of the trench T2 (see FIGS. 7 to 9) and the p-column formed by performing the oblique ion implantation into the side surface S3 of the trench T2 (see FIG. 9) can be each formed with a stable amount of impurities. As a result, it is possible to prevent variations in the characteristics (withstand voltage) of the power MOSFET and, thereby, improve the reliability of the semiconductor device.

### Modification Example

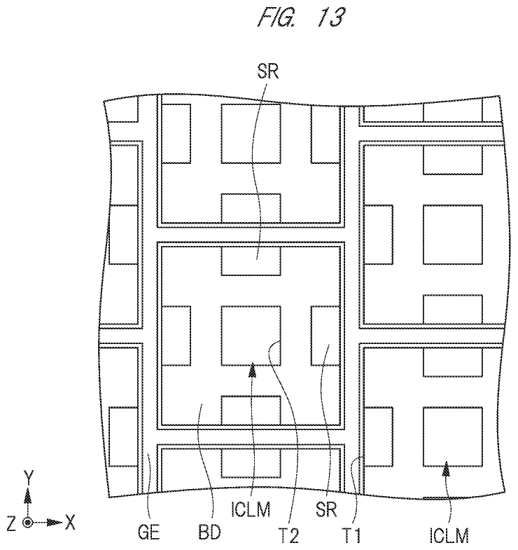

FIG. 13 shows a planar layout of a power MOSFET of this modification example. A cross-sectional structure and a manufacturing method of the power MOSFET of this modification example are the same as those described with reference to FIGS. 2 to 12.

FIG. 1 shows a layout for forming the gate electrode and the p-column that extend in one direction in a plan view, but as shown in FIG. 13, the n-column and the gate electrode may be formed so as to surround each periphery of a plurality of p-columns formed like lands in a plan view.

As shown in FIG. 13, each of the trench T2 and the insulator column ICLM in the trench T2 has a rectangular layout in a plan view, and is formed in a columnar shape. Here, the diffusion layer PD (not shown) is formed adjacent to the trench T2 so as to surround the trench T2 in a plan view. The trench T1 and the gate electrode GE are formed apart from the trench T2 and the diffusion layer PD so as to surround the trench T2 (insulator column ICLM) and the diffusion layer PD (p-column) in a plan view. That is, each of the trench T1 and the gate electrode GE is formed in a square frame shape in a plan view around one trench T2. The source region SR is formed adjacent to the trench T1 between each of four sides of the trench T2 in a plan view and a side of the gate electrode GE facing each of the four sides in a plan view.

The plurality of trenches T2 are arranged alongside at regular intervals in the Y direction to form a first row. Further, in the X direction, a second row similar to the above-mentioned row composed of the plurality of trenches T2 is arranged. However, the second row is formed at a position shifted by half a cycle in the Y direction with respect to the first row. That is, the trenches T2 are arranged in a staggered pattern.

Here, the crystal plane of the first main surface of the semiconductor substrate is the (110) plane as in the semiconductor device described with reference to FIGS. 1 and 2. Further, the crystal plane on each side surface of the trenches T1 and T2 in the X direction is the (111) planes. That is, each of the side surface of the trench T2 and the side surface of the trench T1 facing the above-mentioned side surface in a plan view is formed parallel to the (111) plane.

Therefore, the semiconductor device of this modification example and the method of manufacturing the same can obtain the same effects as those described with reference to FIGS. 2 to 12.

Although the invention made by the present inventors has been specifically described above based on the embodiments, the present invention is not limited to the above-mentioned embodiments and, needless to say, can be variously modified without departing from the scope thereof.

For example, each conductive type of the semiconductor region and the semiconductor layer constituting the semiconductor device described in the above-mentioned embodiments may be inverted.

What is claimed is:

1. A semiconductor device comprising:
a semiconductor substrate having a first main surface whose crystal plane is a (110) plane, and a second main surface on an opposite side to the first main surface;
a drift layer of first conductive type, the drift layer being arranged in the semiconductor substrate;
a body region of second conductive type, the body region being arranged on a side of the first main surface of the drift layer in the second substrate, the second conductive type being different from the first conductive type;
a source region of a first conductive type, the source region being arranged on a side of the first main surface of the body region in the semiconductor substrate;
a gate insulating film arranged on a portion of the body region that is sandwiched between the drift layer and the source region;
a gate electrode interposing the gate insulating film and facing the portion of the body region;
a first trench formed in a middle depth of the semiconductor substrate from the first main surface, a side surface of the first trench contacting with the body region and the drift layer;
a first insulating film embedded in the first trench; and
a semiconductor region of the second conductive type, the semiconductor region being formed in the side surface of the first trench,
wherein a crystal plane of the side surface of the first trench is a (111) plane.

2. The semiconductor device according to claim 1,
wherein the side surface of the first trench is perpendicular to the first main surface.

3. The semiconductor device according to claim 1, further comprising a second trench formed in a middle depth of the semiconductor substrate from the first main surface, a side surface of the second trench contacting with the body region,
wherein a crystal plane of the side surface of the second trench is a (111) plane.

4. The semiconductor device according to claim 3,
wherein a depth of the second trench is shallower than a depth of the first trench.

5. The semiconductor device according to claim 3,
wherein the gate electrode is embodied into the second trench via the gate insulating film.

6. A method of manufacturing a semiconductor device, comprising:
(a) preparing a semiconductor substrate of a first conductive type, the semiconductor substrate having a first main surface whose crystal plane is a (110) plane and a second main surface on an opposite side to the first main surface;
(b) forming a gate electrode on the semiconductor substrate via a gate insulating film;
(c) forming a first trench in the first main surface by wet etching using TMAH, the first trench reaching a middle depth of the semiconductor substrate, a crystal plane of a side surface of the first trench being a (111) plane;
(d) forming a body region of a second conductive type on a side of the first main surface, the body region interposing the gate electrode and facing the gate electrode, the second conductive type being different from the first conductive type; and
(e) forming a source region of a first conductive type in the first main surface adjacent to the gate electrode in a plan view.

7. The method of manufacturing a semiconductor device according to claim 6, further comprising:
(a1) before the (b), forming a second trench that reaches a middle depth of the semiconductor substrate from the first main surface, a crystal plane of a side surface of the second trench being a (111) plane.

8. The method of manufacturing a semiconductor device according to claim 7,
wherein a depth of the second trench is shallower than a dept of the first trench.

9. The method of manufacturing a semiconductor device according to claim 8,
wherein, in (b), the gate electrode is formed via the gate insulating film in the second trench.
